(19) United States
(12) Patent Application Publication
(10) Pub. No.: US 2026/0156903 A1
(43) Pub. Date: Jun. 4, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Yuichiro HINATA, Matsumoto-city (JP); Naoyuki KANAI, Matsumoto-city (JP)

(73) Assignee: FUJI ELECTRIC CO., LTD., Kawasaki-shi (JP)

(21) Appl. No.: 19/464,064

(22) Filed: Jan. 29, 2026

Related U.S. Application Data
(63) Continuation of application No. PCT/JP2024/045841, filed on Dec. 25, 2024.

(30) Foreign Application Priority Data
Mar. 15, 2024 (JP) 2024-041115

(51) Int. Cl. H10D 80/20; H10W 40/25; H10W 90/00; H10W 90/10

(52) U.S. Cl. CPC H10D 80/20; H10W 40/255; H10W 90/10; H10W 90/734

(57) ABSTRACT

Provided is a semiconductor device with a configuration contributing to a decrease in size. The semiconductor device includes an insulated circuit substrate provided with conductive layers on the top surface side, semiconductor chips provided on the conductive layers, a wiring substrate provided on the semiconductor chips, and an output terminal having one end side and a negative-electrode terminal having one end side, each one end side being located between the conductive layers and the wiring substrate. The semiconductor device further includes inter-substrate connection pins having upper end sides inserted with pressure to first penetration holes provided in the wiring substrate and lower end sides inserted with pressure to second penetration holes provided in top surfaces of the output terminal and the negative-electrode terminal.

### CROSS-REFERENCE TO RELATED APPLICATION

This application is a Continuation of PCT Application No. PCT/JP2024/045841,filed on Dec. 25, 2024, and claims the priority of Japanese Patent Application No. 2024-041115, filed on Mar. 15, 2024, the content of which are incorporated herein by reference.

### TECHNICAL FIELD

The present disclosure relates to semiconductor devices and methods of manufacturing the semiconductor devices.

### BACKGROUND ART

Semiconductor devices conventionally disclosed have a configuration including an insulated circuit substrate, semiconductor chips provided on the insulated circuit substrate, a wiring substrate provided on the semiconductor chips, and external connection terminals provided on the insulated circuit substrate (for example, refer to WO2019/171684A1, JP2014-236150A and JPH10-41460A).

WO2019/171684A1 discloses a configuration in which a semiconductor element is provided on a flat part of a circuit member, a resin layer is provided on the semiconductor element, a conductive layer is provided on the resin layer, and a conductive spacer is interposed between the conductive layer and the circuit member. JP2014-236150A discloses a configuration in which a wiring substrate is provided above semiconductor chips, external connection terminals are connected to the wiring substrate or a conductive layer, and the external terminals are inserted to holes of busbars. JPH10-41460A discloses a configuration in which leg pieces of a main terminal provided with holes are soldered onto a substrate of a power circuit block. Such conventional semiconductor devices typically have a configuration in which distances between the respective constituent members are largely kept so as not to interfere with each other during a process of assembling the semiconductor devices.

### SUMMARY OF THE INVENTION

### Technical Problem

The distances largely kept between the respective constituent members can lead to an increase in size of such a semiconductor device. The increase in size of the semiconductor device also leads to an increase in size of a capacitor connected to the external terminals, a cooling member connected to the bottom surface of the semiconductor device, and further a casing housing these semiconductor members, resulting in an increase in cost.

In view of the foregoing problems, the present disclosure provides a semiconductor device having a configuration contributing to a decrease in size, and also provides a method of manufacturing the semiconductor device.

### Solution to Problem

To solve the problems described above, a semiconductor device according to an aspect of the present disclosure includes an insulated circuit substrate provided with a conductive layer on a top surface side, a semiconductor chip provided on the conductive layer, a wiring substrate provided on the semiconductor chip, an external connection terminal having one end side located between the conductive layer and the wiring substrate, and an inter-substrate connection pin having an upper end side inserted with pressure to a first penetration hole provided in the wiring substrate and a lower end side inserted with pressure to a second penetration hole provided in the external connection terminal.

The lower end side of the inter-substrate connection pin may penetrate through the second penetration hole to be bonded to a top surface of the conductive layer.

The upper end side of the inter-substrate connection pin may be electrically connected to a wiring layer provided in the wiring substrate, and the lower end side may be electrically connected to the conductive layer.

The semiconductor device may further include a sealing resin provided to seal the semiconductor chip and the wiring substrate, the external connection terminal may include a first external terminal, a second external terminal, and a third external terminal, the first external terminal and the second external terminal may each have one end side bonded to the conductive layer via a bonding member, and another end side projecting to extend parallel to each other from a first side surface of the sealing resin, and the third external terminal may have one end side bonded to the conductive layer via a bonding member, and another end side projecting to extend from a second side surface of the sealing resin opposite to the first side surface.

The conductive layer may include a recess having an opening on a top surface side, and the lower end side of the inter-substrate connection pin may be inserted with pressure to the recess.

A maximum width of a part of the inter-substrate connection pin inserted with pressure to the recess may be smaller than a maximum width of a part of the inter-substrate connection pin inserted with pressure to the second penetration hole.

An outer diameter of the inter-substrate connection pin may be 0.4 millimeters or greater and 2.0 millimeters or smaller.

A method of manufacturing a semiconductor device according to another aspect of the present disclosure, the semiconductor device including an insulated circuit substrate provided with a conductive layer on a top surface side, a semiconductor chip provided on the conductive layer, a wiring substrate provided on the semiconductor chip, an external connection terminal having one end side located between the conductive layer and the wiring substrate, and an inter-substrate connection pin having an upper end side inserted with pressure to a first penetration hole provided in the wiring substrate and a lower end side inserted with pressure to a second penetration hole provided in the external connection terminal, includes inserting the inter-substrate connection pin with pressure to the first penetration hole and the second penetration hole to provide an integrated member in which the wiring substrate and the external connection terminal are integrated together via the inter-substrate connection pin, and then bonding the integrated member to the insulated circuit substrate and the semiconductor chip together.

The summary of the invention as described above does not encompass all of the features necessary for the present invention. Any subcombination of the groups of the features can be a part of the invention.

### BRIEF DESCRIPTION OF THE DRAWINGS

FIG. 1 is a view illustrating a planar configuration of a semiconductor device according to an embodiment;

FIG. 2 is a view illustrating a cross-sectional configuration of the semiconductor device taken along line A-A in FIG. 1;

FIG. 3 is a view illustrating a cross-sectional configuration of the semiconductor device taken along line B-B in FIG. 1;

FIG. 4 is a view illustrating a cross-sectional configuration of an integrated member;

FIG. 5 is an enlarged view illustrating an inter-substrate connection pin;

FIG. 6 is a view illustrating a cross section of the inter-substrate connection pin in a width direction in FIG. 5;

FIG. 7 is a flowchart showing a method of manufacturing the semiconductor device according to the embodiment;

FIG. 8 is a view illustrating a sequential step of the method of manufacturing the semiconductor device;

FIG. 9 is a view illustrating a sequential step of the method of manufacturing the semiconductor device;

FIG. 10 is a view illustrating a sequential step of the method of manufacturing the semiconductor device;

FIG. 11 is a view illustrating a sequential step of the method of manufacturing the semiconductor device;

FIG. 12 is a view illustrating a sequential step of the method of manufacturing the semiconductor device;

FIG. 13 is a view illustrating a sequential step the method of manufacturing the semiconductor device;

FIG. 14 is a view illustrating a sequential step of the method of manufacturing the semiconductor device;

FIG. 15 is a view illustrating a sequential step of the method of manufacturing the semiconductor device;

FIG. 16 is a view illustrating a sequential step of the method of manufacturing the semiconductor device;

FIG. 17 is a view illustrating a planar configuration of a semiconductor device of a comparative example;

FIG. 18 is a view illustrating a cross-sectional configuration of the semiconductor device taken along line C-C in FIG. 17;

FIG. 19 is a view illustrating a method of manufacturing the semiconductor device of the comparative example;

FIG. 20 is a flowchart showing the method of manufacturing the semiconductor device of the comparative example;

FIG. 21 is a view illustrating a step of assembling the semiconductor device of the comparative example;

FIG. 22 is a view illustrating a step of assembling the semiconductor device according to the embodiment;

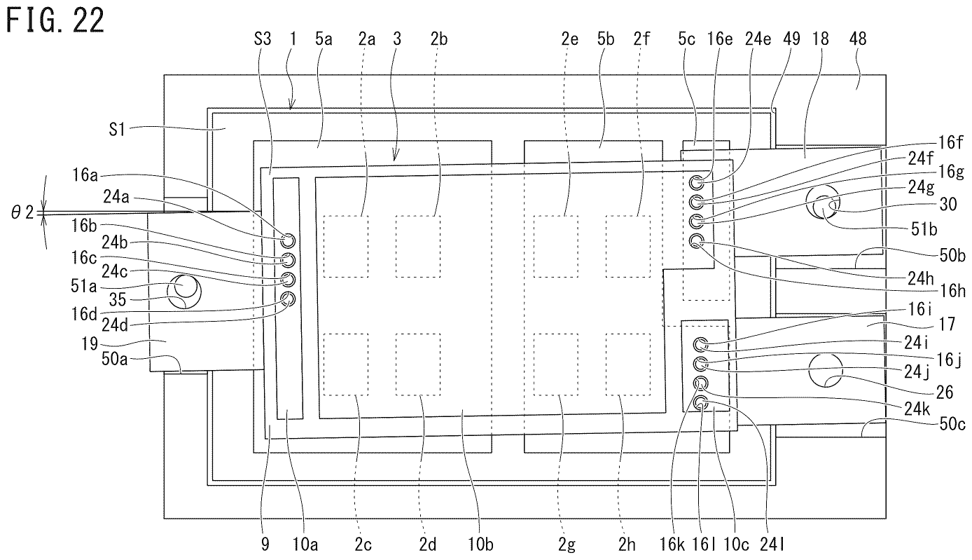

FIG. 23 is a view illustrating a cross-sectional configuration of a semiconductor device according to a modified example;

FIG. 24 is an enlarged view illustrating an inter-substrate connection pin; and

FIG. 25 is a view illustrating a cross section of the inter-substrate connection pin in a width direction illustrated in FIG. 24.

### DETAILED DESCRIPTION

A semiconductor device and an example of a method of manufacturing the same according to an embodiment of the present disclosure are described below with reference to the drawings.

In the following descriptions of the drawings, the same or similar components are denoted by the same or similar reference numerals, and overlapping explanations are omitted below. It should be understood that the drawings are schematic illustrations, and the relations between thicknesses and planar dimensions, or the proportions of thicknesses of layers illustrated are not drawn to scale. It should also be understood that the relations or proportions of the dimensions between the drawings may differ from each other. The embodiment described below illustrates devices and methods for embodying the technical idea of the present disclosure, which is not intended to limit the materials, shapes, structures, or arrangements of the constituent members to those as disclosed herein.

In the following descriptions, the directional definitions such as an upper-lower direction and a right-left direction are made simply for illustration purposes, and are not intended to limit the technical idea of the present disclosure. For example, when a direction of a target is turned by 90 degrees and is observed, the upper-lower direction should be changed to the right-left direction, and when the direction of the target is turned by 180 degrees, the upper-lower direction should be reversed. The embodiment of the present disclosure is described below in the order as follows:
1. Entire Configuration of Semiconductor Device
2. Method of Manufacturing Semiconductor Device
3. Operations and Effects
4. Modified Example

### 1. Entire Configuration of Semiconductor Device

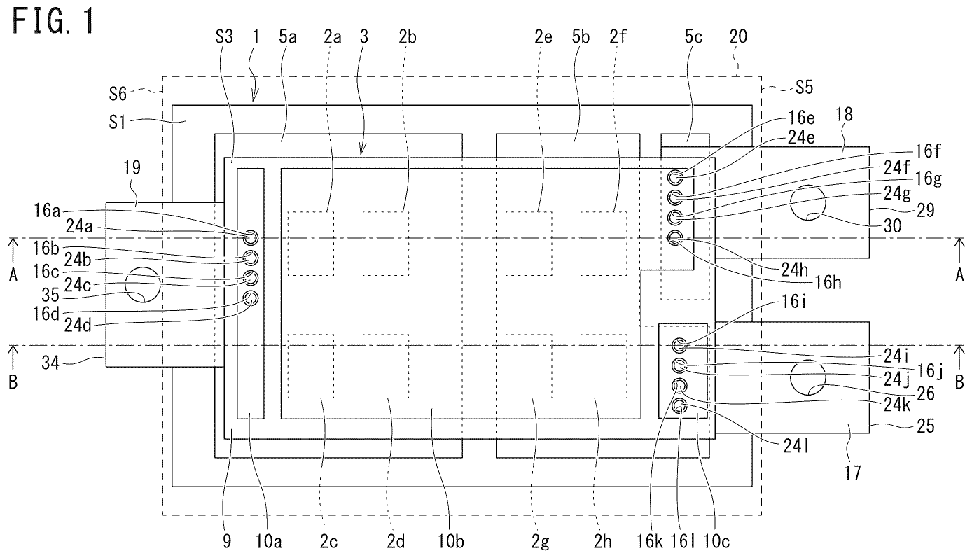

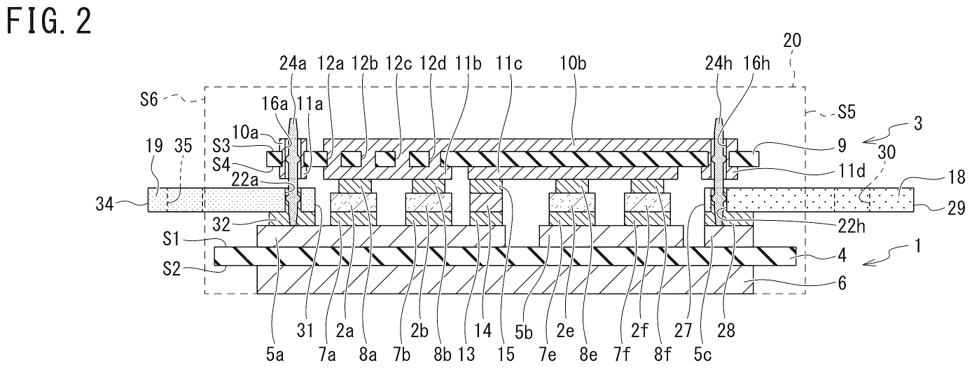

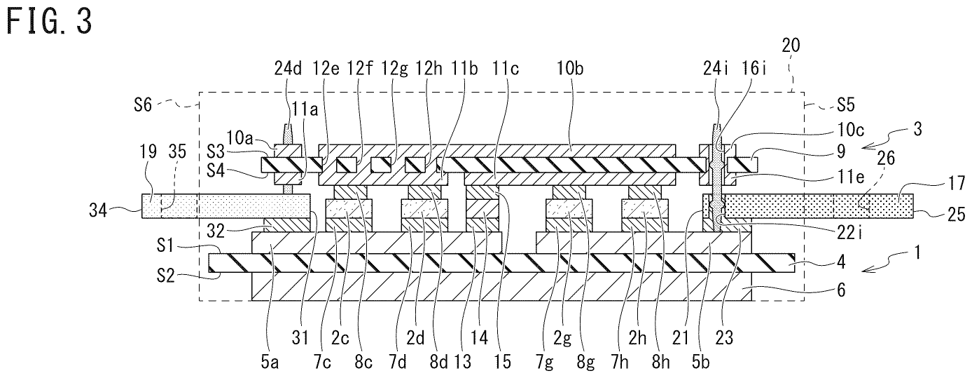

FIG. 1 is a view illustrating a planar configuration of the semiconductor device according to the present embodiment. FIG. 2 is a view illustrating a cross-sectional configuration of the semiconductor device taken along line A-A in FIG. 1. FIG. 3 is a view illustrating a cross-sectional configuration of the semiconductor device taken along line B-B in FIG. 1. FIG. 1 to FIG. 3 each indicate a sealing resin 20 by the broken line, and illustrate the inner configuration in the sealing resin 20. As illustrated in FIG. 1 to FIG. 3, the semiconductor device according to the present embodiment is a power semiconductor module including power semiconductor elements (also referred to below as “semiconductor chips”), which are each a semiconductor element for electric power. The semiconductor device can control revolutions per minute and acceleration of a motor connected to an inverter (not illustrated), for example.

The semiconductor device includes an insulated circuit substrate 1, semiconductor chips 2a to 2h provided on the insulated circuit substrate 1, and a wiring substrate 3 provided on the semiconductor chips 2a to 2h.

The insulated circuit substrate 1 is a direct copper bonded (DCB) substrate or an active metal brazed (AMB) substrate, for example. The insulated circuit substrate 1 includes an insulating layer 4, conductive layers 5a to 5c provided on a top surface S1 side of the insulating layer 4, and a cooling plate 6 provided on a bottom surface S2 side of the insulating layer 4.

The insulating layer 4 is a ceramic plate mainly including aluminum oxide (Al₂O₃), aluminum nitride (AlN), silicon nitride (Si₃N₄), or boron nitride (BN), or a resin insulating layer including polymer material, for example. The cooling plate 6 is not necessarily provided when a resin insulating layer is used as the insulating layer 4. The insulating layer 4 is provided in a rectangular plate-like state with the top surface S1 facing upward.

The conductive layers 5a to 5c and the cooling plate 6 are each a conductive film including copper (Cu), aluminum (Al), or the like, for example. As illustrated in FIG. 1, the conductive layer 5a is provided in a rectangular film-like state in a region toward one end side of the top surface S1 of the insulating layer 4 in the longitudinal direction (in the left-side region in FIG. 1). The conductive layer 5b is provided in an L-shaped film-like state with a part of the rectangle cut off in a region toward the other end side of the top surface S1 of the insulating layer 4 in the longitudinal direction (in the right-side region in FIG. 1). FIG. 1 illustrates the case in which the L-shape is obtained such that the upper-right corner of the rectangle is cut off. The conductive layer 5c is provided in a rectangular film-like state in the cut-off part of the conductive layer 5b in the region at the other end side (at the upper-right corner in FIG. 1).

The present embodiment is illustrated with a case in which the semiconductor chips 2a to 2h are each an insulated gate bipolar transistor (IGBT). The respective semiconductor chips 2a to 2h may be a metal-oxide semiconductor field-effect transistor (MOSFET), a static induction (SI) thyristor, a gate turn-off (GTO) thyristor, a diode, or the like instead. The respective semiconductor chips 2a to 2h are implemented by a semiconductor substrate including silicon (Si), silicon carbide (SiC), gallium nitride (GaN), or gallium oxide (Ga₂O₃), for example. The semiconductor chips 2a to 2d are arranged into an array of 2×2 on the conductive layer 5a. The semiconductor chips 2e to 2h are arranged into an array of 2×2 on the conductive layer 5b.

The semiconductor chips 2a to 2h each include a collector electrode (not illustrated) provided on the bottom surface side, and an emitter electrode (not illustrated) and a gate electrode (not illustrated) provided on the top surface side. The collector electrodes of the semiconductor chips 2a to 2d are bonded to the conductive layer 5a of the insulated circuit substrate 1 via bonding members 7a to 7d such as solder and sintering material (copper or silver, for example). Similarly, the collector electrodes of the semiconductor chips 2e to 2h are bonded to the conductive layer 5b of the insulated circuit substrate 1 via bonding members 7e to 7h such as solder and sintering material. The emitter electrodes of the semiconductor chips 2a to 2d are bonded to the bottom surface side of the wiring substrate 3 (a lower-side circuit pattern 11b described below) via bonding members 8a to 8d such as solder and sintering material. Similarly, the emitter electrodes of the semiconductor chips 2e to 2h are bonded to the bottom surface side of the wiring substrate 3 (a lower-side circuit pattern 11c) via bonding members 8e to 8h such as solder and sintering material. The gate electrodes of the semiconductor chips 2a to 2h are electrically connected to a control terminal (not illustrated) via bonding wires, for example. The respective semiconductor chips 2a to 2h are controlled such that current flowing between the collector electrodes and the emitter electrodes is turned ON/OFF when ON/OFF electric signals are sent to the gate electrodes and the emitter electrodes, so as to control the revolutions per minute and the acceleration of the motor connected to the inverter.

The wiring substrate 3 includes an insulating layer 9, upper-side circuit patterns 10a to 10c provided on the top surface S3 side of the insulating layer 9, and lower-side circuit patterns 11a to 11d provided on the bottom surface S4 side of the insulating layer 9. The wiring substrate 3 is arranged over the semiconductor chips 2a to 2h.

The insulating layer 9 is a ceramic plate mainly including aluminum oxide (Al₂O₃), aluminum nitride (AlN), silicon nitride (Si₃N₄), or boron nitride (BN), or a resin insulating layer including polymer material, for example. The insulating layer 9 is provided into a rectangular plate-like state, in which the top surface S3 faces upward, and the bottom surface S4 faces downward so as to be opposed to the semiconductor chips 2a to 2h.

The upper-side circuit patterns 10a to 10c and the lower-side circuit patterns 11a to 11d are each a conductive film including copper (Cu) and aluminum (Al), for example. As illustrated in FIG. 1, the upper-side circuit pattern 10a is provided in a rectangular film-like state in a region toward one end side of the top surface S3 of the insulating layer 9 in the longitudinal direction (in the left-side region in FIG. 1) so as to overlap with an inner-side end of an output terminal 19 (described below) in a planar view. One of the ends of the output terminal 19 located inside the sealing resin 20 is referred to below as an “inner-side end”, and the other end of the output terminal 19 located outside the sealing resin 20 is referred to below as an “outer-side end”. The same definitions regarding the “inner-side end” and the “outer-side end” are also applied to a positive-electrode terminal 17 and a negative-electrode terminal 18. FIG. 1 illustrates the case in which the upper-side circuit pattern 10a is arranged along the width direction of the insulating layer 9. Similarly, the upper-side circuit pattern 10b is provided in an L-shaped film-like state with a part of the rectangle cut off in a region across the middle and toward the other end side of the top surface S3 in the longitudinal direction (in the left-side region in FIG. 1). FIG. 1 illustrates the case in which the L-shape is obtained such that the lower-right corner of the rectangle is cut off. The upper-side circuit pattern 10c is provided in a rectangular film-like state in a region toward the other end side in the cut-off part of the upper-side circuit pattern 10b (at the lower-right corner in FIG. 1) so as to overlap with an inner-side end of the positive-electrode terminal 17 (described below) in a planar view.

The lower-side circuit pattern 11a is provided in a rectangular film-like state in a region of the bottom surface S4 of the insulating layer 9 overlapping with the upper-side circuit pattern 10a (in the left-side region in FIG. 1) in a planar view. The lower-side circuit pattern 11b is provided in a rectangular film-like state in a region of the bottom surface S4 overlapping with the upper-side circuit pattern 10b and also overlapping with the semiconductor chips 2a to 2d in a planar view. FIG. 2 and FIG. 3 each illustrate the case in which the lower-side circuit pattern 11b is electrically connected to the upper-side circuit pattern 10b through a plurality of penetration holes 12a to 12h provided in the insulating layer 9. The lower-side circuit pattern 11c is provided in a rectangular film-like state in a region of the bottom surface S4 overlapping with the upper-side circuit pattern 10b and also overlapping with the semiconductor chips 2e to 2h (in the region on the right side of the lower-side circuit pattern 11b in FIG. 2) in a planar view. The lower-side circuit pattern 11c is electrically connected to the conductive layer 5a of the insulated circuit substrate 1 through a bonding member 13, a conductive layer 14, and a bonding member 15. The lower-side circuit pattern 11d is provided in a rectangular film-like state in a region of the bottom surface S4 overlapping with the upper-side circuit pattern 10b and also overlapping with an inner-side end of the negative-electrode terminal 18 (at the upper-right corner in FIG. 1) in a planar view. The lower-side circuit pattern 11e is provided in a rectangular film-like state in a region of the bottom surface S4 overlapping with the upper-side circuit pattern 10c and also overlapping with an inner-side end of the positive-electrode terminal 17 (at the lower-right corner in FIG. 1) in a planar view.

The wiring substrate 3 is provided with first penetration holes 16a to 16l penetrating through the insulating layer 9, the upper-side circuit patterns 10a to 10c, and the lower-side circuit patterns 11a, 11d, and 11e in the thickness direction. The first penetration holes 16a to 16d are aligned in the width direction of the output terminal 19 (in the upper-lower direction in FIG. 1) at a position overlapping with the inner-side end of the output terminal 19 in a planar view. Similarly, the first penetration holes 16e to 16h are aligned in the width direction of the negative-electrode terminal 18 (in the upper-lower direction in FIG. 1) at a position overlapping with the inner-side end of the negative-electrode terminal 18 in a planar view. The first penetration holes 16i to 16l are aligned in the width direction of the positive-electrode terminal 17 (in the upper-lower direction in FIG. 1) at a position overlapping with the inner-side end of the positive-electrode terminal 17 in a planar view.

The semiconductor device includes the plural external connection terminals (also referred to below as the “positive-electrode terminal 17”, the “negative-electrode terminal 18”, and the “output terminal 19”) with the respective one ends (the inner-side ends) interposed between the insulated circuit substrate 1 and the wiring substrate 3, and the sealing resin 20 having a cuboidal shape for sealing the semiconductor chips 2a to 2h and the wiring substrate 3. The positive-electrode terminal 17 is an example of “a first external terminal”. Similarly, the negative-electrode terminal 18 is an example of “a second external terminal”, and the output terminal 19 is an example of “a third external terminal”.

The positive-electrode terminal 17, the negative-electrode terminal 18, and the output terminal 19 are each a plate-like member including copper (Cu), a copper alloy, aluminum (Al), or an aluminum alloy, for example. When metal having bad solderability such as aluminum (Al) and an aluminum alloy is used, the respective surfaces are plated with nickel (Ni) or silver (Ag). The positive-electrode terminal 17 to the output terminal 19 are each formed into a rectangular plate-like shape with one surface facing upward. The positive-electrode terminal 17 to the output terminal 19 each have a thickness set in a range of 0.6 millimeters or greater and 2.0 millimeters or smaller, for example. The respective thicknesses of the positive-electrode terminal 17 to the output terminal 19 may be either common to or different from each other. The respective widths of the positive-electrode terminal 17 to the output terminal 19 may also be either common to or different from each other.

As illustrated in FIG. 3, one end 21 side of the positive-electrode terminal 17 (the inner-side end part; the left end part in FIG. 3) in the longitudinal direction is located between the insulated circuit substrate 1 and the wiring substrate 3, and is bonded to the conductive layer 5b of the insulated circuit substrate 1 via a bonding member 23 such as solder and sintering material. The positive-electrode terminal 17 is electrically connected to the electrodes (the collector electrodes) on the lower side of the semiconductor chips 2e to 2h via the bonding member 23, the conductive layer 5b, and the bonding members 7e to 7h. The one end 21 (the inner-side end part), which is a part overlapping with the upper-side circuit pattern 10c and the lower-side circuit pattern 11e of the wiring substrate 3 in a planar view, is provided with a plurality of second penetration holes (FIG. 3 illustrates a second penetration hole 22i). The second penetration holes are provided at the positions overlapping with the first penetration holes 16i to 16l of the wiring substrate 3 in a planar view. Namely, the second penetration holes in the positive-electrode terminal 17 are aligned in series in the width direction of the positive-electrode terminal 17. Inter-substrate connection pins 24i to 24l (FIG. 3 illustrates an inter-substrate connection pin 24i) are inserted with pressure into the second penetration holes of the positive-electrode terminal 17 (FIG. 3 illustrates the second penetration hole 22i). In particular, the lower end sides of the inter-substrate connection pins 24i to 24l are inserted with pressure into the second penetration holes (FIG. 3 illustrates the second penetration hole 22i), and the upper end sides are inserted with pressure into the first penetration holes (FIG. 3 illustrates the first penetration hole 16i) located at the positions overlapping with the second penetration holes in a planar view. The wiring substrate 3 and the positive-electrode terminal 17 are thus integrated together via the inter-substrate connection pins 24i to 24l, so as to suppress a mutual movement between the wiring substrate 3 and the positive-electrode terminal 17. The number of the inter-substrate connection pins 24i to 24l is two or more, so as to also suppress a mutual rotation between the wiring substrate 3 and the positive-electrode terminal 17. While FIG. 3 illustrates the structure around the inter-substrate connection pin 24i of the inter-substrate connection pins 24i to 24l as an example, the structures around the other inter-substrate connection pins are substantially common to that as illustrated.

The lower end sides of the inter-substrate connection pins 24i to 24l penetrate through the second penetration holes of the positive-electrode terminal 17 (FIG. 3 illustrates the second penetration hole 22i) so as to be bonded to the top surface of the conductive layer 5b via the bonding member 23 for bonding to the positive-electrode terminal 17. The upper end sides of the inter-substrate connection pins 24i to 24l penetrate through the first penetration holes 16i to 16l so as to project from the openings at the upper parts of the first penetration holes 16i to 16l.

During the operation of the semiconductor device, current as large as several hundred amperes flows through the wiring substrate 3, the positive-electrode terminal 17, the negative-electrode terminal 18, and the output terminal 19. When such a large amount of current I flows through the wiring substrate 3, the positive-electrode terminal 17, the negative-electrode terminal 18, and the output terminal 19, Joule heat P (=I²×R) is caused due to electric resistance R at the current-flowing parts. If heat-releasing paths to the outside of the semiconductor device are not provided, the semiconductor device would be filled with heat. To deal with this, the present embodiment has the configuration in which the wiring substrate 3, the positive-electrode terminal 17, and the like are connected to the insulated circuit substrate 1 via the inter-substrate connection pins 24i to 24l, so as to provide heat-releasing paths to the cooling plate 6 and thus prevent the inside of the semiconductor device from being filled with heat. Namely, the inter-substrate connection pins 24i to 24l have the functions capable of integrating the wiring substrate 3 and the positive-electrode terminal 17 and also capable of preventing the inside of the semiconductor device from being filled with heat. Further, the positive-electrode terminal 17 and the conductive layer 5b are connected to each other via the bonding member 23, so as to reduce the electric resistance R at the current-flowing parts, reduce the Joule heat P, and thus prevent the inside of the semiconductor device from being filled with heat more reliably.

The other end 25 side of the positive-electrode terminal 17 (the outer-side end part; the right end part in FIG. 3) projects from one of the side surfaces of the sealing resin 20 (also referred to below as a “first side surface S5”; the right surface in FIG. 3) in the longitudinal direction to further extend in a direction substantially orthogonal to the first side surface S5. The other end 25 (the outer-side end part) side of the positive-electrode terminal 17 is provided with a fixation hole 26 penetrating the positive-electrode terminal 17 in the thickness direction.

As illustrated in FIG. 2, one end 27 side of the negative-electrode terminal 18 (the inner-side end part; the left end part in FIG. 2) in the longitudinal direction is located between the insulated circuit substrate 1 and the wiring substrate 3, and is bonded to the conductive layer 5c of the insulated circuit substrate 1 via a bonding member 28 such as solder and sintering material. The one end 27, which is a part overlapping with the upper-side circuit pattern 10b and the lower-side circuit pattern 11d of the wiring substrate 3 in a planar view, is provided with a plurality of second penetration holes (FIG. 2 illustrates a second penetration hole 22h). The second penetration holes are provided at the positions overlapping with the first penetration holes 16e to 16h of the wiring substrate 3 in a planar view. Namely, the second penetration holes of the negative-electrode terminal 18 are aligned in series in the width direction of the negative-electrode terminal 18. Inter-substrate connection pins 24e to 24h (FIG. 2 illustrates an inter-substrate connection pin 24h) are inserted with pressure into the second penetration holes of the negative-electrode terminal 18 (FIG. 2 illustrates the second penetration holes 22h). In particular, the lower end sides of the inter-substrate connection pins 24e to 24h are inserted with pressure into the second penetration holes (FIG. 2 illustrates the second penetration hole 22h), and the upper end sides are inserted with pressure into the first penetration holes (FIG. 2 illustrates the first penetration hole 16h) located at the positions overlapping with the second penetration holes in a planar view. The wiring substrate 3 and the negative-electrode terminal 18 are thus integrated together via the inter-substrate connection pins 24e to 24h, so as to suppress a mutual movement between the wiring substrate 3 and the negative-electrode terminal 18. The number of the inter-substrate connection pins 24e to 24h is two or more, so as to also suppress a mutual rotation between the wiring substrate 3 and the negative-electrode terminal 18. The wiring substrate 3, the negative-electrode terminal 18, and the like are connected to the insulated circuit substrate 1 via the inter-substrate connection pins 24e to 24h, so as to provide heat-releasing paths to the cooling plate 6 and thus prevent the inside of the semiconductor device from being filled with heat. Further, the negative-electrode terminal 18 and the conductive layer 5c are connected to each other via the bonding member 28, so as to reduce the electric resistance R, reduce the Joule heat P, and thus prevent the inside of the semiconductor device from being filled with heat more reliably. While FIG. 2 illustrates the structure around the inter-substrate connection pin 24h of the inter-substrate connection pins 24e to 24h as an example, the structures around the other inter-substrate connection pins are substantially common to that as illustrated.

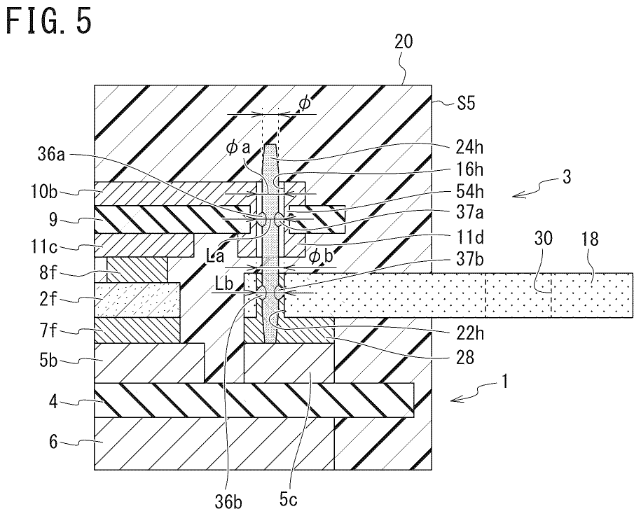

The lower end sides of the inter-substrate connection pins 24e to 24h penetrate through the second penetration holes of the negative-electrode terminal 18 (FIG. 2 illustrates the second penetration hole 22h) so as to be bonded and electrically connected to the top surface of the conductive layer 5c via the bonding member 28 for bonding to the negative-electrode terminal 18. The upper end sides of the inter-substrate connection pins 24e to 24h penetrate through the first penetration holes 16e to 16h so as to be electrically connected to the upper-side circuit pattern 10b and the lower-side circuit pattern 11d via plating layers (refer to FIG. 5; FIG. 5 illustrates a plating layer 54h) provided on the inner surfaces of the first penetration holes 16e to 16h. The upper-side circuit pattern 10b and the lower-side circuit pattern 11d are each an example of a “wiring layer of the wiring substrate”. FIG. 5 illustrates the case in which the plating layer 54h is provided integrally with the upper-side circuit pattern 10b and the lower-side circuit pattern 11d. The upper-side circuit pattern 10b and the lower-side circuit pattern 11d of the wiring substrate 3 are thus electrically connected to the conductive layer 5c of the insulated circuit substrate 1 via the inter-substrate connection pins 24e to 24h. Namely, the inter-substrate connection pins 24e to 24h have the functions capable of integrating the wiring substrate 3 and the negative-electrode terminal 18, capable of preventing the inside of the semiconductor device from being filled with heat, and capable of electrically connecting the wiring substrate 3 and the negative-electrode terminal 18 to each other. While FIG. 5 illustrates the structure around the inter-substrate connection pin 24h in the negative-electrode terminal 18 as an example, the structures around the other inter-substrate connection pins are substantially common to that as illustrated.

The other end 29 side of the negative-electrode terminal 18 (the outer-side end part; the right end part in FIG. 2) projects from the first side surface S5 of the sealing resin 20 to further extend parallel to the extending direction of the positive-electrode terminal 17. Namely, the other end 25 side of the positive-electrode terminal 17 and the other end 29 side of the negative-electrode terminal 18 each project from the first side surface S5 of the sealing resin 20 to extend parallel to each other. The other end 29 side of the negative-electrode terminal 18 (the outer-side end part) is provided with a fixation hole 30 penetrating the negative-electrode terminal 18 in the thickness direction.

As illustrated in FIG. 2, one end 31 side of the output terminal 19 (the inner-side end part; the right end part in FIG. 2) in the longitudinal direction is located between the insulated circuit substrate 1 and the wiring substrate 3, and is bonded to the conductive layer 5a of the insulated circuit substrate 1 via a bonding member 32 such as solder and sintering material. The output terminal 19 is electrically connected to the electrodes (the collector electrodes) on the lower side of the semiconductor chips 2a to 2d via the bonding member 32, the conductive layer 5a, and the bonding members 7a to 7d. The one end 31 (the inner-side end part), which is a part overlapping with the upper-side circuit pattern 10a and the lower-side circuit pattern 11a of the wiring substrate 3 in a planar view, is provided with a plurality of second penetration holes (FIG. 2 illustrates a second penetration hole 22a). The second penetration holes are provided at the positions overlapping with the first penetration holes 16a to 16d of the wiring substrate 3 in a planar view. Namely, the second penetration holes of the output terminal 19 are aligned in series in the width direction of the output terminal 19. Inter-substrate connection pins 24a to 24d (FIG. 2 illustrates an inter-substrate connection pin 24a) are inserted with pressure into the second penetration holes of the output terminal 19 (FIG. 2 illustrates the second penetration holes 22a). In particular, the lower end sides of the inter-substrate connection pins 24a to 24d are inserted with pressure into the second penetration holes (FIG. 2 illustrates the second penetration hole 22a), and the upper end sides are inserted with pressure into the first penetration holes (FIG. 2 illustrates the first penetration hole 16a) located at the positions overlapping with the second penetration holes in a planar view. The wiring substrate 3 and the output terminal 19 are thus integrated together via the inter-substrate connection pins 24a to 24d, so as to suppress a mutual movement between the wiring substrate 3 and the output terminal 19. The number of the inter-substrate connection pins 24a to 24d is two or more, so as to also suppress a mutual rotation between the wiring substrate 3 and the output terminal 19. While FIG. 2 illustrates the structure around the inter-substrate connection pin 24a of the inter-substrate connection pins 24a to 24d as an example, the structures around the other inter-substrate connection pins are substantially common to that as illustrated.

The wiring substrate 3, the output terminal 19, and the like are connected to the insulated circuit substrate 1 via the inter-substrate connection pins 24a to 24d, so as to provide heat-releasing paths to the cooling plate 6 and thus prevent the inside of the semiconductor device from being filled with heat. Namely, the inter-substrate connection pins 24a to 24d have the functions capable of integrating the wiring substrate 3 and the output terminal 19 and also capable of preventing the inside of the semiconductor device from being filled with heat. Further, the output terminal 19 and the conductive layer 5a are connected to each other via the bonding member 32, so as to reduce the electric resistance R, reduce the Joule heat P, and thus prevent the inside of the semiconductor device from being filled with heat more reliably.

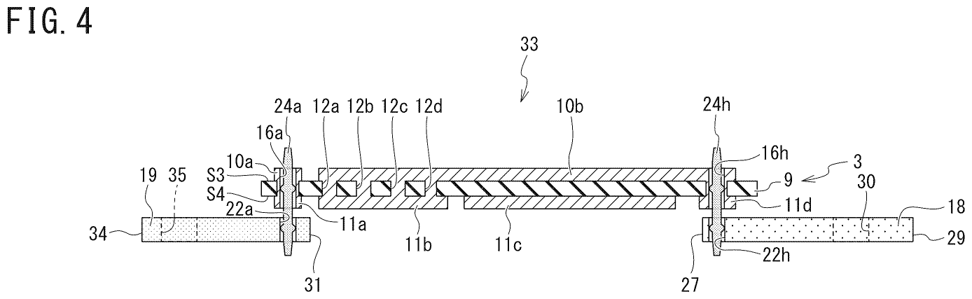

The integration between the wiring substrate 3 and the positive-electrode terminal 17, the integration between the wiring substrate 3 and the negative-electrode terminal 18, and the integration between the wiring substrate 3 and the output terminal 19 as described above lead the wiring substrate 3, the positive-electrode terminal 17, the negative-electrode terminal 18, and the output terminal 19 to implement an integrated member 33, as illustrated in FIG. 4.

The lower end sides of the inter-substrate connection pins 24a to 24d penetrate through the second penetration holes of the output terminal 19 (FIG. 2 illustrates the second penetration hole 22a) so as to be bonded to the top surface of the conductive layer 5a via the bonding member 32 for bonding to the output terminal 19. The upper end sides of the inter-substrate connection pins 24a to 24d penetrate through the first penetration holes 16a to 16d to further project from the openings provided at the upper parts of the first penetration holes 16a to 16d.

The other end 34 of the output terminal 19 (the outer-side end part; the left end part in FIG. 2) projects from the side surface opposite to the first side surface S5 of the sealing resin 20 (also referred to below as a “second side surface S6”; the left surface in FIG. 2) to further extend in a direction substantially orthogonal to the second side surface S6. The other end 34 (the outer-side end part) side of the output terminal 19 is provided with a fixation hole 35 penetrating the output terminal 19 in the thickness direction.

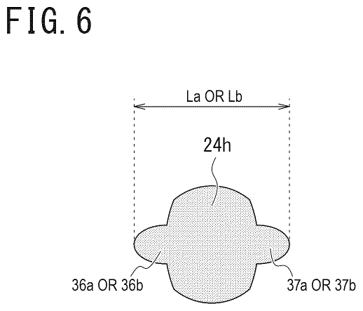

As illustrated in FIG. 5, the inter-substrate connection pins 24a to 24l are each a cylindrical stick-like member including copper (Cu), a copper alloy, aluminum (Al), and an aluminum alloy, for example. The respective upper and lower ends of the inter-substrate connection pins 24a to 24l have a tapered shape. This structure can facilitate the insertion of the tip parts of the inter-substrate connection pins 24a to 24l into the first penetration holes 16a to 16l and the second penetration holes (FIG. 5 illustrates the second penetration hole 22h) during the assembling process. The respective parts of the inter-substrate connection pins 24a to 24l inserted with pressure into the first penetration holes 16a to 16l (FIG. 5 illustrates the first penetration hole 16h) are provided with protrusions 36a and 37a protruding in the directions opposite to each other, as illustrated in FIG. 5 and FIG. 6. The respective parts inserted with pressure into the second penetration holes (FIG. 5 illustrates the second penetration hole 22h) are also provided with protrusions 36b and 37b protruding in the directions opposite to each other. FIG. 6 is a cross-sectional view of the inter-substrate connection pin 24h in a width direction illustrated in FIG. 5. A maximum width La of the part provided with the protrusions 36a and 37a and a maximum width Lb of the part provided with the protrusions 36b and 37b are each larger by several percents than an inner diameter φa of the respective first penetration holes 16a to 16l and an inner diameter φb of the respective second penetration holes (FIG. 5 illustrates the second penetration hole 22h). The protrusions 36a, 37a, 36b, and 37b, when inserted with pressure into the inter-substrate connection pins 24a to 24l, are thus elastically deformed to cause surface pressure so as to be bonded to the first penetration holes 16a to 16l and the second penetration holes (FIG. 5 illustrates the second penetration hole 22h). FIG. 5 illustrates the case in which the dimensions of the corresponding parts are defined as La=Lb>φa=φb.

A part (an upper part) of the respective bonding members 23, 28, and 32 for bonding to the positive-electrode terminal 17, the negative-electrode terminal 18, and the output terminal 19 is inserted into the respective gaps between the inter-substrate connection pins 24a to 24l not provided with the protrusions 36b and 37b and the second penetration holes (FIG. 5 illustrates the second penetration hole 22h).

An outer diameter φ of the respective inter-substrate connection pins 24a to 24l is set in a range of 0.4 millimeters or greater and 2.0 millimeters or smaller, for example. If the outer diameter φ of the respective inter-substrate connection pins 24a to 24l is smaller than 0.4 millimeters, buckling may be caused in the inter-substrate connection pins 24a to 24l during the pressure insertion of the inter-substrate connection pins 24a to 24l. If the outer diameter φ of the respective inter-substrate connection pins 24a to 24l is greater than 2.0 millimeters, which is greater than the respective thicknesses of the positive-electrode terminal 17, the negative-electrode terminal 18, and the output terminal 19, perpendicularity of the inter-substrate connection pins 24a to 24l may be degraded. The outer diameter φ of the respective inter-substrate connection pins 24a to 24l can correspond to an outer diameter of a part inserted with pressure into the respective first penetration holes 16a to 16l and the respective second penetration holes (FIG. 5 illustrates the second penetration hole 22h), or a part excluding the respective upper and lower tapered parts, namely, the cylindrical stick-shaped part, for example.

The sealing resin 20 seals the insulated circuit substrate 1, the semiconductor chips 2a to 2h, the wiring substrate 3, the positive-electrode terminal 17, the negative-electrode terminal 18, the output terminal 19, and the like. The sealing resin 20 as used herein can be thermosetting silicone gel or insulating sealing resin such as epoxy resin, for example.

### 2. Method of Manufacturing Semiconductor Device

An example of a method of manufacturing the semiconductor device according to the present embodiment is described below with reference to the drawings.

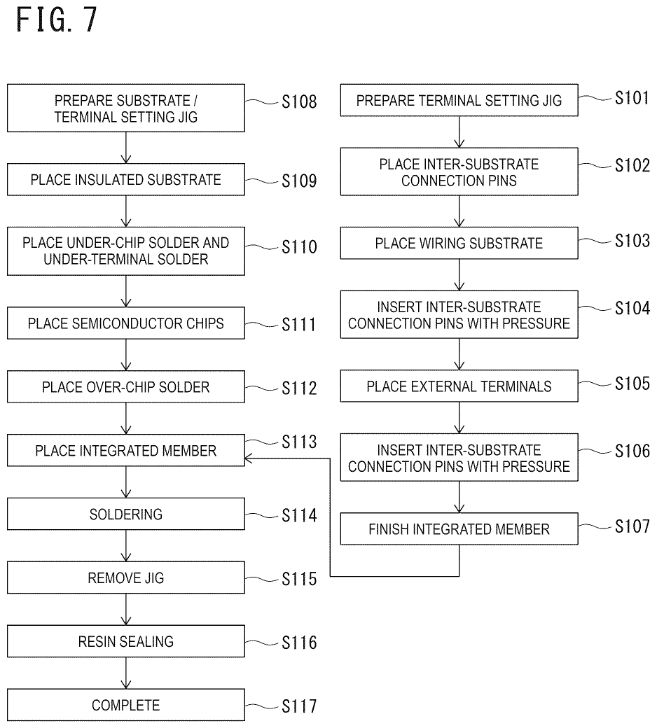

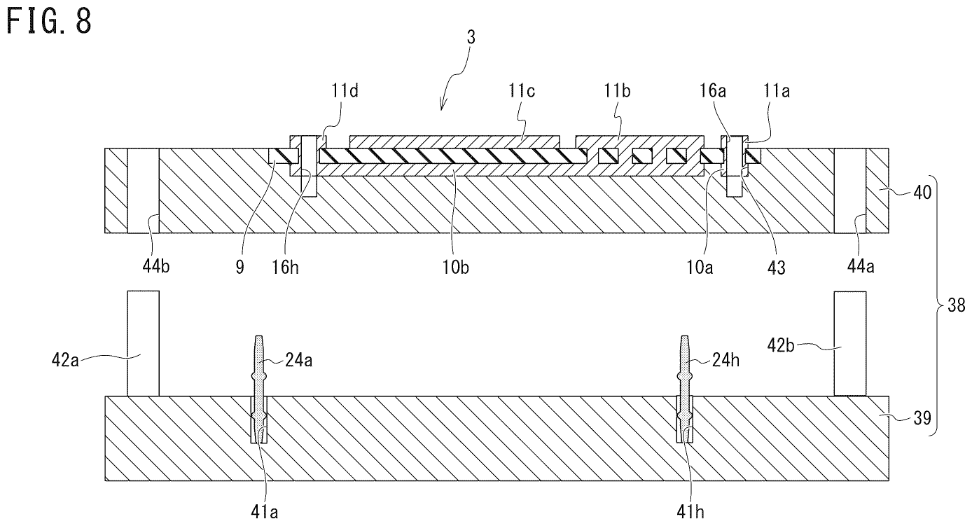

FIG. 7 is a flowchart showing the method of manufacturing the semiconductor device according to the present embodiment. FIG. 8 to FIG. 16 are views illustrating the respective steps of the method of manufacturing the semiconductor device according to the present embodiment.

As illustrated in FIG. 8, a terminal setting jig 38 is prepared first (step S101 in FIG. 7). The terminal setting jig 38 includes a first lower jig 39 and an upper jig 40. The top surface of the first lower jig 39 is provided with a plurality of recesses (FIG. 8 illustrates recesses 41a and 41h) for supporting the respective inter-substrate connection pins 24a to 24l, and fixation protrusions 42a and 42b. The top surface of the upper jig 40 is provided with a recess 43 for housing the wiring substrate 3, and fixation holes 44a and 44b fitted with the fixation protrusions 42a and 42b. Next, the inter-substrate connection pins 24a to 24l are placed in the recesses 41a, 41h, and the like of the first lower jig 39 (step S102 in FIG. 7). Next, the wiring substrate 3 is placed in the recess 43 of the upper jig 40 (step S103 in FIG. 7). The upper jig 40 is positioned with the opening of the recess 43 directed upward. The wiring substrate 3 is positioned with the upper-side circuit patterns 10a to 10c opposed to the bottom surface of the recess 43.

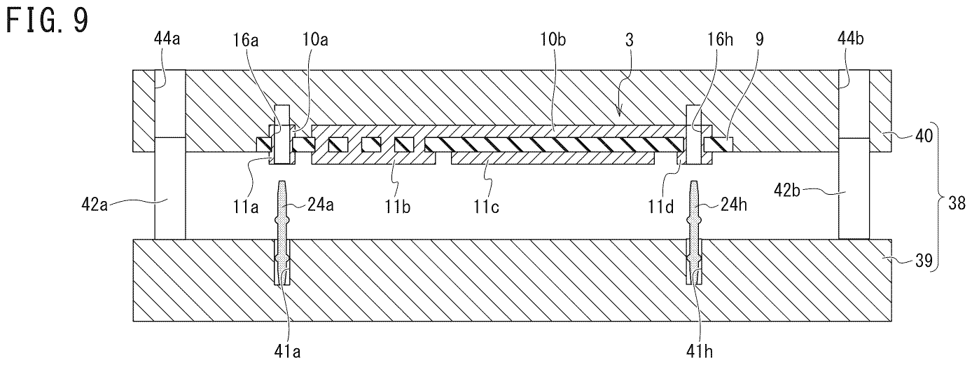

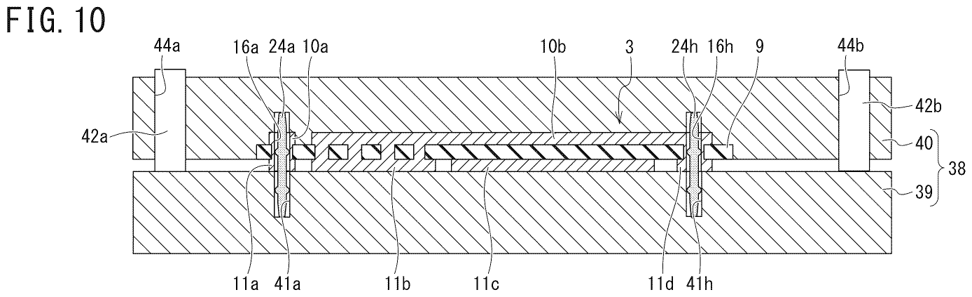

Next, as illustrated in FIG. 9, the upper and lower sides of the upper jig 40 are inverted to be placed on the first lower jig 39 so that the fixation protrusions 42a and 42b are fitted to the fixation holes 44a and 44b. Next, as illustrated in FIG. 10, the upper jig 40 is pushed downward so that the inter-substrate connection pins 24a to 24l are inserted with pressure into the first penetration holes 16a to 16l of the wiring substrate 3 (step S104 in FIG. 7). This step integrates the wiring substrate 3 and the inter-substrate connection pins 24a to 24l together.

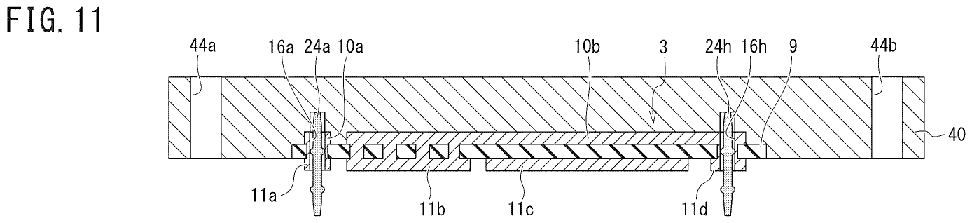

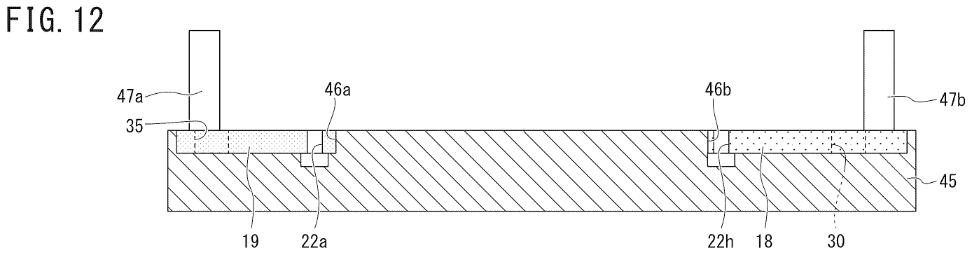

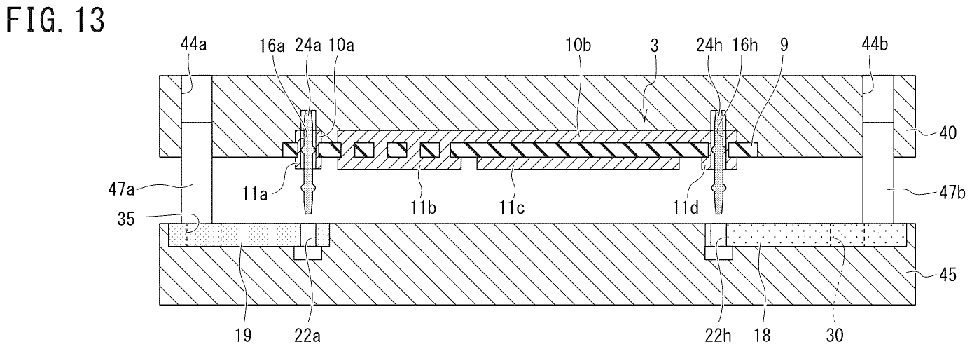

Next, as illustrated in FIG. 11, the first lower jig 39 is removed. Next, as illustrated in FIG. 12, a second lower jig 45 is prepared. The top surface of the second lower jig 45 is provided with a plurality of recesses (FIG. 12 illustrates recesses 46a and 46b) for positioning the positive-electrode terminal 17, the negative-electrode terminal 18, and the output terminal 19, and is also provided with fixation protrusions 47a and 47b. Next, as illustrated in FIG. 13, the upper jig 40 is placed on the second lower jig 45 so that the fixation protrusions 47a and 47b and the fixation holes 44a and 44b are fitted together (step S105 in FIG. 7). Next, the upper jig 40 is pushed downward so that the inter-substrate connection pins 24a to 24l are inserted with pressure into the second penetration holes of the positive-electrode terminal 17, the negative-electrode terminal 18, and the output terminal 19 (FIG. 13 illustrates the second penetration holes 22a and 22h) (step S106 in FIG. 7). This step integrates the wiring substrate 3, the positive-electrode terminal 17, the negative-electrode terminal 18, and the output terminal 19 together via the inter-substrate connection pins 24a to 24l so as to finish the integrated member 33 illustrated in FIG. 4. Namely, the method of manufacturing the semiconductor device according to the present embodiment first executes the pressure insertion of the inter-substrate connection pins 24a to 24l into the first penetration holes 16a to 16l and the second penetration holes (FIG. 13 illustrates the second penetration holes 22a and 22h) so as to provide the integrated member 33 in which the wiring substrate 3, the positive-electrode terminal 17, the negative-electrode terminal 18, and the output terminal 19 are integrated together via the inter-substrate connection pins 24a to 24l. Next, the upper jig 40 and the second lower jig 45 are removed so that the integrated member 33 is extracted (step S107 in FIG. 7).

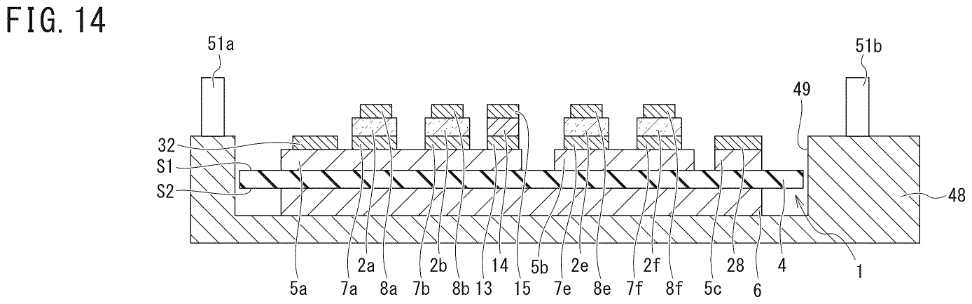

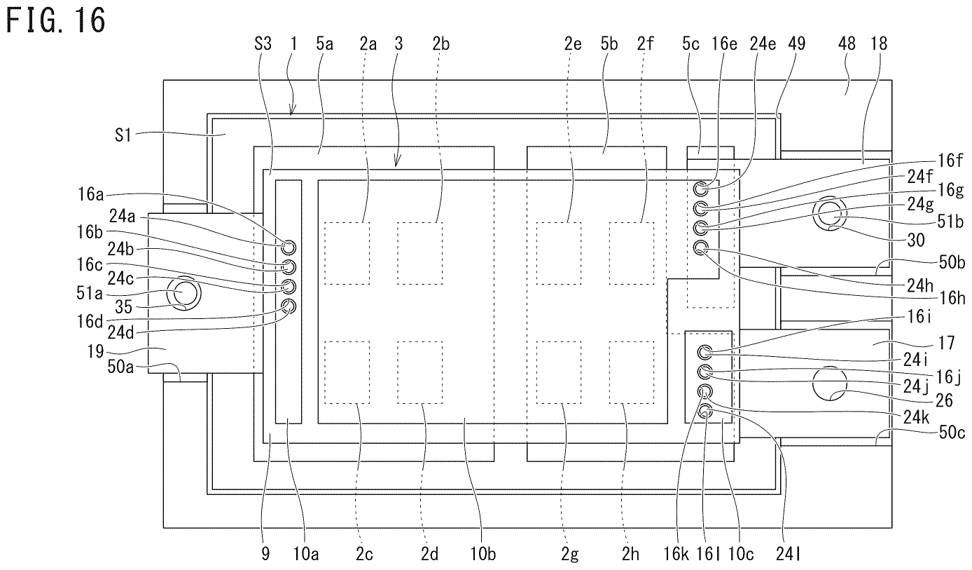

Next, as illustrated in FIG. 14, a substrate/terminal setting jig 48 is prepared (step S108 in FIG. 7). The top surface of the substrate/terminal setting jig 48 is provided with a recess 49 for housing the insulated circuit substrate 1, grooves 50a, 50b, and 50c (refer to FIG. 16) for housing the output terminal 19, the negative-electrode terminal 18, and the positive-electrode terminal 17, and fixation protrusions 51a and 51b provided inside the grooves 50a and 50b. Next, the insulated circuit substrate 1 is placed in the recess 49 of the substrate/terminal setting jig 48, and the bonding members 7a to 7h, 13, 23, 28, and 32 (under-chip solder, under-terminal solder)→the semiconductor chips 2a to 2h and the conductive layer 14→the bonding members 8a to 8h and 15 (over-chip solder) are then sequentially mounted on the insulated circuit substrate 1 in this order (steps S109 to S112 in FIG. 7). This step provides the part of the semiconductor device under the integrated member 33.

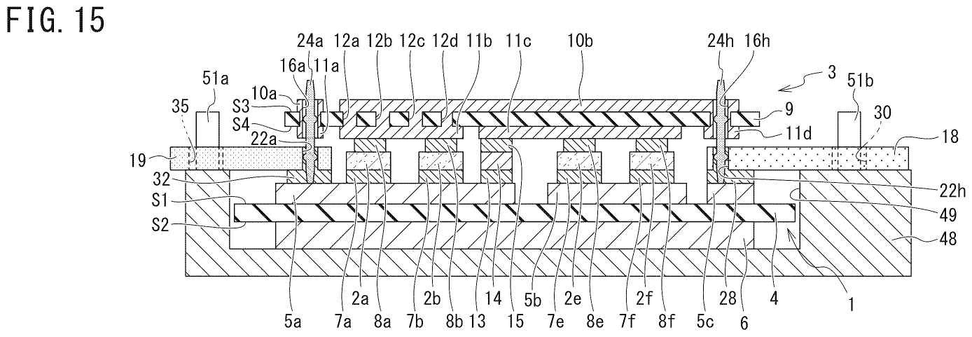

Next, as illustrated in FIG. 15 and FIG. 16, the integrated member 33 is mounted on the insulated circuit substrate 1 so that the fixation protrusions 51a and 51b of the substrate/terminal setting jig 48 are fitted to the fixation holes 35 and 30 of the output terminal 19 and the negative-electrode terminal 18 (step S113 in FIG. 7). FIG. 16 is a view illustrating a planar configuration of the substrate/terminal setting jig 48 illustrated in FIG. 15. FIG. 16 illustrates a case in which the fixation protrusions 51a and 51b are only provided at the positions fitted to the fixation holes 35 and 30 of the output terminal 19 and the negative-electrode terminal 18. Next, the entire components are heated to fuse the bonding members 7a to 7h, 13, 23, 28, 32, 8a to 8h, and 15 so as to bond the integrated member 33, the semiconductor chips 2a to 2h, and the conductive layer 14 together (step S114 in FIG. 7). Namely, the manufacturing method according to the present embodiment first provides the integrated member 33 and then bonds the integrated member 33 to the insulated circuit substrate 1 and the semiconductor chips 2a to 2h. Subsequently, the substrate/terminal setting jig 48 is removed (step S115 in FIG. 7). Thereafter, the integrated member 33, the insulated circuit substrate 1, the positive-electrode terminal 17, the negative-electrode terminal 18, the semiconductor chips 2a to 2h, and the conductive layer 14 bonded together are placed in a metal die for resin sealing (not illustrated) so as to be injected with the sealing resin 20 to execute the resin sealing (step S116 in FIG. 7).

The semiconductor device as illustrated in FIG. 1 to FIG. 3 is thus completed (step S117 in FIG. 7).

### 3. Operations and Effects

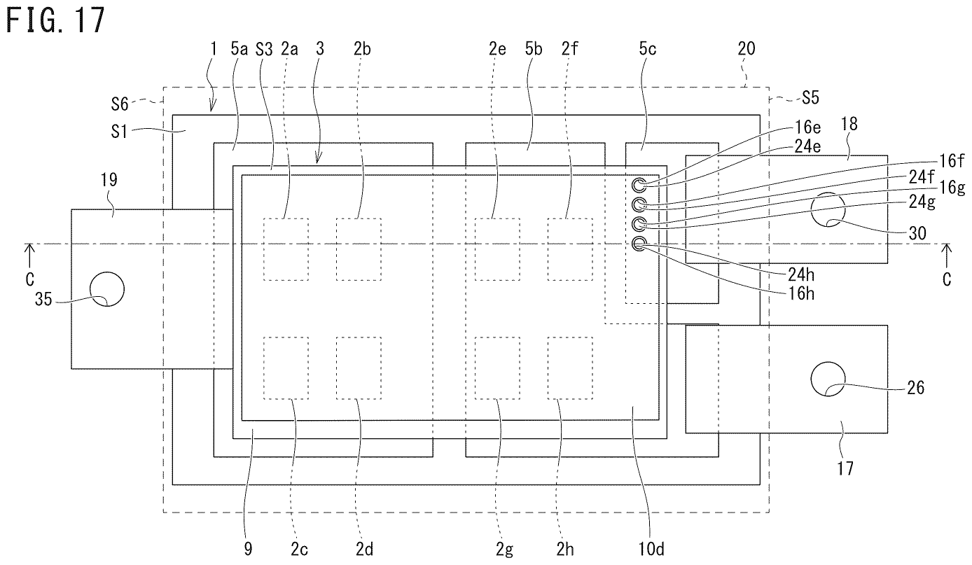

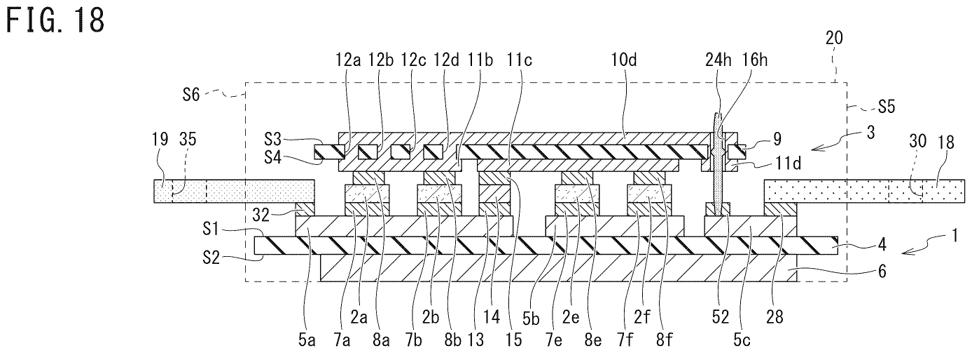

An example of a semiconductor device of a comparative example is described below with reference to FIG. 17 and FIG. 18. FIG. 18 is a view illustrating a cross-sectional configuration of the semiconductor device taken along line C-C in FIG. 17. As illustrated in FIG. 17 and FIG. 18, the semiconductor device of the comparative example differs from the semiconductor device according to the present embodiment illustrated in FIG. 1 to FIG. 3 in that the wiring substrate 3, the positive-electrode terminal 17, the negative-electrode terminal 18, and the output terminal 19 illustrated in FIG. 1 are not integrated together, namely, the integrated member 33 illustrated in FIG. 4 is not provided. In particular, the semiconductor device of the comparative example has a configuration in which the inter-substrate connection pins 24e to 24h illustrated in FIG. 1 are provided separately from the negative-electrode terminal 18, while the other inter-substrate connection pins 24a to 24d, and 24i to 24l are eliminated. In addition, a bonding member 52 for bonding the inter-substrate connection pins 24e to 24h to the insulated circuit substrate 1 is further provided independently of the bonding member 28 for bonding the negative-electrode terminal 18 to the insulated circuit substrate 1. Further, an integrated upper-side circuit pattern 10d is used, instead of the upper-side circuit patterns 10a to 10c provided independently of each other.

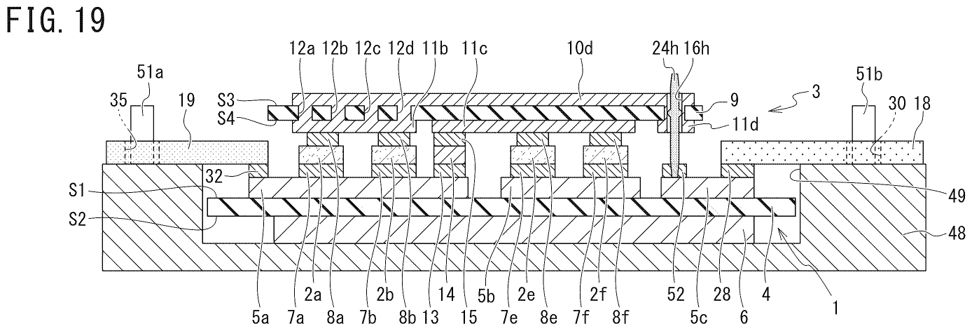

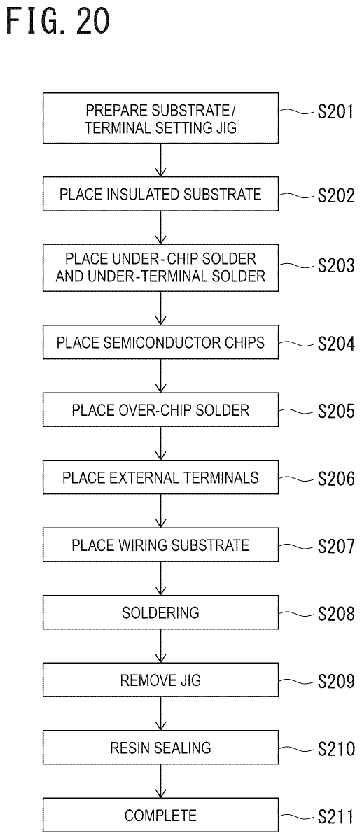

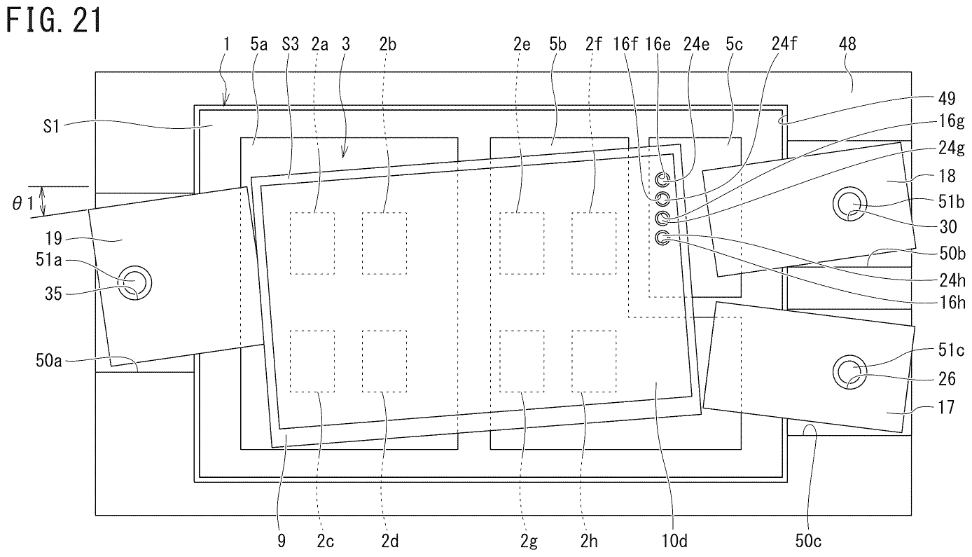

Upon the assembly of the semiconductor device of the comparative example, the insulated circuit substrate 1 is first positioned in the recess 49 of the substrate/terminal setting jig 48, as illustrated in FIG. 19 (step S201 in FIG. 20). The top surface of the substrate/terminal setting jig 48 is provided with the recess 49 for housing the insulated circuit substrate 1, the grooves 50a to 50c (refer to FIG. 21) for housing the output terminal 19, the negative-electrode terminal 18, and the positive-electrode terminal 17, and the fixation protrusions 51a to 51c (refer to FIG. 21) provided in the grooves 50a to 50c. Next, the bonding members 7a to 7h, 13, 23, 28, 32, and 52 (under-chip solder, under-terminal solder)→the semiconductor chips 2a to 2h and the conductive layer 14→the bonding members 8a to 8h and 15 (over-chip solder)→the positive-electrode terminal 17, the negative-electrode terminal 18, and the output terminal 19→the wiring substrate 3 are sequentially mounted on the insulated circuit substrate 1 in this order (steps S202 to 205 in FIG. 20). Next, the bonding members 7a to 7h, 13, 23, 28, 32, and 52 are fused to execute soldering (step S208 in FIG. 20), the substrate/terminal setting jig 48 is removed (step S209 in FIG. 20), and resin sealing with the sealing resin 20 by use of a metal die is executed (step S210 in FIG. 20). The semiconductor device of the comparative example is thus completed (step S211 in FIG. 20).

In the semiconductor device of the comparative example manufactured by the assembling procedure/manufacturing procedure as described above, (1) when the wiring substrate 3 has a smaller size than the insulated circuit substrate 1, the wiring substrate 3 is hard to fix by the recess 49 of the substrate/terminal setting jig 48, and the shape of the substrate/terminal setting jig 48 then needs to be complicated. (2) If the shape of the substrate/terminal setting jig 48 is configured to be complicated, and a gap between the respective components of the semiconductor device and the substrate/terminal setting jig 48 is decreased, for example, it is hard to position the components to the substrate/terminal setting jig 48. If the gap between the respective components of the semiconductor device and the substrate/terminal setting jig 48 (the gap between each of the positive-electrode terminal 17, the negative-electrode terminal 18, and the output terminal 19 and the respective grooves 50c, 50b, and 50a, for example) is increased in order to facilitate the positioning of the components, a positional displacement of the components may be caused to further lead to interference between the respective components. (3) If a distance between the respective components (a distance between the wiring substrate 3 and each of the positive-electrode terminal 17, the negative-electrode terminal 18, and the output terminal 19, for example) is increased in order to prevent the interference between the respective components derived from a positional displacement, an increase in size of the semiconductor device can be caused. The increase in size of the semiconductor device could further lead to an increase in size of a capacitor (not illustrated) connected to the positive-electrode terminal 17 and the like, an increase in size of a cooling member (not illustrated) connected to the bottom of the semiconductor device, and an increase in size of a casing (not illustrated) housing the semiconductor device, causing an increase in cost accordingly. A decrease in size of the semiconductor device is thus strongly required. However, the configuration and the method of manufacturing the semiconductor device of the comparative example described above go against such a requirement.

Particularly in the semiconductor device of the comparative example, the wiring substrate 3, the positive-electrode terminal 17, the negative-electrode terminal 18, and the output terminal 19 are not integrated together during the assembly, as illustrated in FIG. 19. The fixation protrusions 51c, 51b, and 51a of the substrate/terminal setting jig 48 are respectively fitted to the fixation holes 26, 30, and 35 of the positive-electrode terminal 17, the negative-electrode terminal 18, and the output terminal 19. Such a structure leads the positive-electrode terminal 17, the negative-electrode terminal 18, and the output terminal 19 to be pivotable on the fixation protrusions 51c, 51b, and 51a, as illustrated in FIG. 21. This increases a rotation angle θ1 of the respective components such as the positive-electrode terminal 17, the negative-electrode terminal 18, and the output terminal 19, and thus degrades the accuracy of positioning of the respective components.

Further, the configuration of the semiconductor device of the comparative example, if the distance between the negative-electrode terminal 18 and the respective inter-substrate connection pins 24e to 24h is small, may cause the bonding member 28 (refer to FIG. 19) under the negative-electrode terminal 18 to be integrated with the bonding member 52 (refer to FIG. 19) under the inter-substrate connection pins 24e to 24h during the assembly, and thus could lead the bonding member 28 under the negative-electrode terminal 18 to be shifted toward the inter-substrate connection pins 24e to 24h. This would decrease the thickness of the bonding member 28 under the negative-electrode terminal 18 by the moved amount.

As compared with the comparative example, the semiconductor device according to the present embodiment has the configuration, as illustrated in FIG. 1 to FIG. 3, including the inter-substrate connection pins 24a to 24l in which the upper end sides are inserted with pressure to the first penetration holes 16a to 16l (refer to FIG. 1) provided in the wiring substrate 3, and the lower end sides are inserted with pressure to the second penetration holes (FIG. 2 and FIG. 3 illustrate the second penetration holes 22a, 22h, and 22i) provided in the positive-electrode terminal 17, the negative-electrode terminal 18, and the output terminal 19. (1) This configuration fixes the insulated circuit substrate 1 by the recess 49 of the substrate/terminal setting jig 48 during the assembly, so as to fix the wiring substrate 3 by the inter-substrate connection pins 24a to 24l and also avoid the complication of the shape of the substrate/terminal setting jig 48, regardless of whether the wiring substrate 3 has a smaller size than the insulated circuit substrate 1. (2) This configuration can also avoid the interference between the wiring substrate 3 and each of the positive-electrode terminal 17, the negative-electrode terminal 18, and the output terminal 19 (the interference between the respective components) during the assembly. (3) The configuration according to the present embodiment thus can decrease the distance between the respective components, so as to contribute to a reduction in size of the semiconductor device accordingly.

Particularly in the semiconductor device according to the present embodiment, the positive-electrode terminal 17, the negative-electrode terminal 18, and the output terminal 19 implement the integrated member 33 during the assembly. Further, the fixation protrusions 51b and 51a of the substrate/terminal setting jig 48 are fitted to the fixation holes 30 and 35 of the negative-electrode terminal 18 and the output terminal 19. Namely, the fixation protrusions 51b and 51a of the substrate/terminal setting jig 48 are inserted to the fixation holes 30 and 35 of the respective external connection terminals projecting in the directions opposite to each other. This configuration thus can decrease the pivoting amount of the integrated member 33 (the wiring substrate 3, the positive-electrode terminal 17, the negative-electrode terminal 18, and the output terminal 19), can decrease a rotation angle θ2 of the respective components such as the positive-electrode terminal 17, the negative-electrode terminal 18, and the output terminal 19 (θ2<θ1), and thus improve the accuracy of positioning of the respective components.

Further, as illustrated in FIG. 5, the semiconductor device according to the present embodiment has the configuration in which the negative-electrode terminal 18 and the respective inter-substrate connection pins 24e to 24h (FIG. 5 illustrates the inter-substrate connection pin 24h) are integrated together so that the bonding member 28 under the negative-electrode terminal 18 can be used also as the bonding member under the respective inter-substrate connection pins 24e to 24h (FIG. 5 illustrates the inter-substrate connection pin 24h). This configuration can avoid a movement of the bonding member 28 under the negative-electrode terminal 18 in the lateral direction, so as to prevent a change in thickness of the bonding member 52 under the negative-electrode terminal 18.

### 4. Modified Example

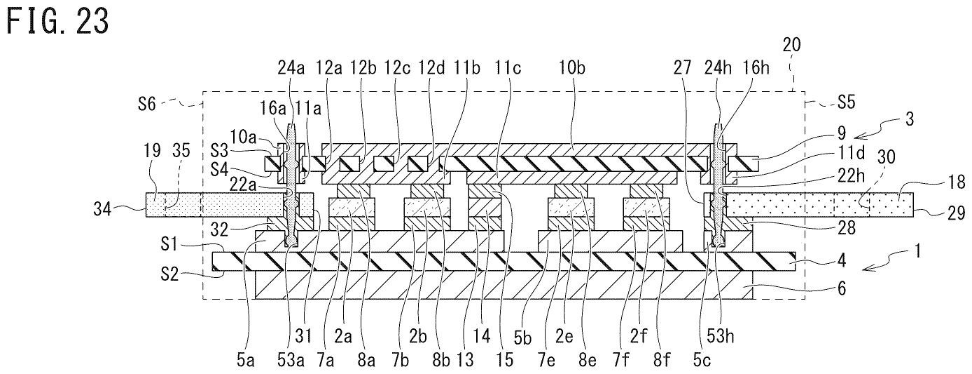

(1) While the present embodiment is illustrated above with the case in which the lower end sides of the inter-substrate connection pins 24a to 24l and the conductive layers 5a to 5c of the insulated circuit substrate 1 are bonded together only via the bonding members 23, 28, and 32, any other configurations may be applied to the present embodiment. For example, as illustrated in FIG. 23, in addition to the bonding with the bonding members 23, 28, and 32, the conductive layers 5a to 5c of the insulated circuit substrate 1 may be provided with a plurality of recesses (FIG. 23 illustrates recesses 53a and 53h) having openings on the top surface side of the conductive layers 5a to 5c so that the lower end sides of the inter-substrate connection pins 24a to 24l (FIG. 23 illustrates the inter-substrate connection pins 24a and 24h) are inserted with pressure into the respective recesses. Such a configuration can improve the accuracy of the mutual positioning between the semiconductor chips 2a to 2h and the wiring substrate 3 on the insulated circuit substrate 1, and improve the connectivity between the wiring substrate 3 and small pads such as gate pads of the semiconductor chips 2a to 2h. While FIG. 23 illustrates an example of the structure around the inter-substrate connection pins 24a and 24h of the inter-substrate connection pins 24a to 24l, the structures around the other inter-substrate connection pins 24b to 24g, and 24i to 24l are also common to that as illustrated.

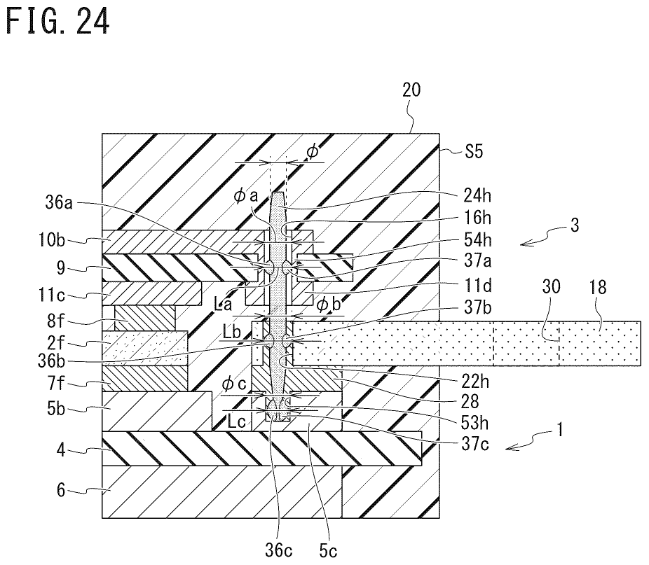

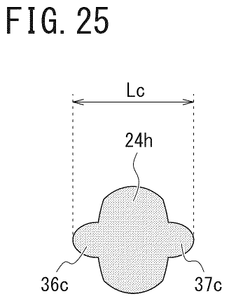

In this case, the lower end sides of the inter-substrate connection pins 24a to 24l, namely, the parts inserted with pressure to the recesses (FIG. 24 illustrates the recess 53h) are provided with protrusions 36c and 37c projecting in the directions opposite to each other, as illustrated in FIG. 24 and FIG. 25. FIG. 25 is a cross-sectional view, in the width direction, illustrating the inter-substrate connection pin 24h illustrated in FIG. 24. A maximum width Lc of the part provided with the protrusions 36c and 37c is greater by several percents than an inner diameter φc of the respective recesses of the conducive layers 5a to 5c (FIG. 24 illustrates the recess 53h). The protrusions 36c and 37c are thus elastically deformed to cause surface pressure during the pressure insertion of the inter-substrate connection pins 24a to 24l, so as to be bonded to the recesses (FIG. 24 illustrates the recess 53h).

The maximum width Lc of the part (the part provided with the protrusions 36c and 37c in FIG. 24) of the respective inter-substrate connection pins 24a to 24l inserted with pressure to the recesses (FIG. 24 illustrates the recess 53h) is set to be smaller than the maximum width Lb of the part (the part provided with the protrusions 36b and 37b in FIG. 24) inserted with pressure to the respective second penetration holes 22a to 22l (Lc<Lb). As illustrated in FIG. 13, the lower end sides of the inter-substrate connection pins 24a to 24l are led to penetrate through the second penetration holes (FIG. 24 illustrates the second penetration hole 22h) during the assembly. If the respective maximum widths would be set to Lc≥Lb, for example, the protrusions 36c and 37c would come in contact with the inner surfaces of the second penetration holes to be deformed when the lower end sides of the inter-substrate connection pins 24a to 24l are led to penetrate through the second penetration holes (FIG. 24 illustrates the second penetration hole 22h), which could decrease the maximum width Lc. Such a deformation would impede the appropriate pressure insertion of the protrusions 36c and 37c into the respective recesses (FIG. 24 illustrates the recess 53h). The semiconductor device according to the present modified example has the configuration defining Lc<Lb, so as to avoid deformation of the protrusions 36c and 37c in the second penetration holes to thus exhibit the pressure insertion of the protrusions 36c and 37c into the recesses (FIG. 24 illustrates the recess 53h) more appropriately.

A depth of the recesses of the conductive layers 5a to 5c (FIG. 24 illustrates the recess 53h) is set to be greater than the outer diameter φ of the respective inter-substrate connection pins 24a to 24l. When the corners defined by the bottom surfaces and the inner wall surfaces of the recesses (FIG. 24 illustrates the recess 53h) are rounded, a depth of a part excluding the rounded part is used. Such a structure can support the lower ends of the inter-substrate connection pins 24a to 24l by the recesses of the conductive layers 5a to 5c appropriately, so as to prevent the perpendicularity of the inter-substrate connection pins 24a to 24l from being degraded.

What is claimed is:

1. A semiconductor device comprising:
an insulated circuit substrate provided with a conductive layer on a top surface side;
a semiconductor chip provided on the conductive layer;
a wiring substrate provided on the semiconductor chip;
an external connection terminal having one end side located between the conductive layer and the wiring substrate; and
an inter-substrate connection pin having an upper end side inserted with pressure to a first penetration hole provided in the wiring substrate and a lower end side inserted with pressure to a second penetration hole provided in the external connection terminal.

2. The semiconductor device of claim 1, wherein the lower end side of the inter-substrate connection pin penetrates through the second penetration hole to be bonded to a top surface of the conductive layer.

3. The semiconductor device of claim 2, wherein the upper end side of the inter-substrate connection pin is electrically connected to a wiring layer provided in the wiring substrate, and the lower end side is electrically connected to the conductive layer.

4. The semiconductor device of claim 1, further comprising a sealing resin provided to seal the semiconductor chip and the wiring substrate,
wherein
the external connection terminal includes a first external terminal, a second external terminal, and a third external terminal,
the first external terminal and the second external terminal each have one end side bonded to the conductive layer via a bonding member, and another end side projecting to extend parallel to each other from a first side surface of the sealing resin, and
the third external terminal has one end side bonded to the conductive layer via a bonding member, and another end side projecting to extend from a second side surface of the sealing resin opposite to the first side surface.

5. The semiconductor device of claim 1, wherein:
the conductive layer includes a recess having an opening on a top surface side; and
the lower end side of the inter-substrate connection pin is inserted with pressure to the recess.

6. The semiconductor device of claim 5, wherein a maximum width of a part of the inter-substrate connection pin inserted with pressure to the recess is smaller than a maximum width of a part of the inter-substrate connection pin inserted with pressure to the second penetration hole.

7. The semiconductor device of claim 1, wherein an outer diameter of the inter-substrate connection pin is 0.4 millimeters or greater and 2.0 millimeters or smaller.

8. A method of manufacturing a semiconductor device including an insulated circuit substrate provided with a conductive layer on a top surface side, a semiconductor chip provided on the conductive layer, a wiring substrate provided on the semiconductor chip, an external connection terminal having one end side located between the conductive layer and the wiring substrate, and an inter-substrate connection pin having an upper end side inserted with pressure to a first penetration hole provided in the wiring substrate and a lower end side inserted with pressure to a second penetration hole provided in the external connection terminal, the method comprising
inserting the inter-substrate connection pin with pressure to the first penetration hole and the second penetration hole to provide an integrated member in which the wiring substrate and the external connection terminal are integrated together via the inter-substrate connection pin, and then bonding the integrated member to the insulated circuit substrate and the semiconductor chip together.
